(19) United States
(12) Patent Application Publication
(10) Pub. No.: US 2014/0168904 A1
(43) Pub. Date: Jun. 19, 2014

(54) WIRELESS INTERNET ROUTER

(71) Applicant: Rammohan Malasani, Taipei (TW)

(72) Inventor: Rammohan Malasani, Taipei (TW)

(21) Appl. No.: 14/060,538

(22) Filed: Oct. 22, 2013

Related U.S. Application Data
(60) Provisional application No. 61/739,152, filed on Dec. 19, 2012.

(51) Int. Cl. H05K 5/02; H05K 1/02

(52) U.S. Cl. CPC H05K 5/0247; H05K 1/0204
USPC 361/720; 361/679.01; 361/760

(57) ABSTRACT

Wireless Internet routers are disclosed. The routers include a casing that has a front side, a backside, a top side, a bottom side, and two additional sides. The casing is configured to house at least one printed circuit board of the router. An indentation area is located in the backside of the casing. The indentation area includes one or more walls, and a surface that meets and is integrally formed with the one or more walls. A plurality of connection ports that are located within the one or more walls of the indentation area (which may be oriented in a variety of positions). The router is configured to visually hide the cables that are attached to the connection ports, regardless of whether the router is oriented in a vertical, horizontal, vertically slanted, or flush wall mounted position.

### CROSS-REFERENCE TO RELATED APPLICATIONS

This application claims priority to, and incorporates by reference, U.S. provisional patent application Ser. No. 61/739,152, filed Dec. 19, 2012.

### FIELD OF THE INVENTION

The field of the present invention relates to network routers and, more particularly, to the field of wireless Internet routers that are configured to visually conceal the cables that are connected thereto, when the router is oriented in a variety of positions.

### BACKGROUND OF THE INVENTION

Wireless Internet routers have become a staple in buildings of all kind, including commercial and residential buildings. Early models of wireless Internet routers often include antennas that protrude vertically from a topside thereof, and include a series of cables and cords that are reversibly connected to the backside (or other areas) of such routers. Although such currently-existing routers are generally effective to deliver a desirable Internet signal, the routers are not visually attractive. More particularly, the openly visible cables and cords that connect to the currently-available routers leave the routers unattractive.

In many cases, users will try to hide the routers in desks or within other furniture to minimize the unwanted visual that is created by such routers. In addition, all of the currently-existing routers that are configured to be securely attached to a vertical wall surface leave a mess of dangling cables, since the connectors are positioned at the edge of the router. The other prior art routers that are configured to hide cables in a vertical orientation typically exhibit connectors on the backside of the router, positioned at a right angle relative to the vertical surface of the router. These routers cannot be mounted to a wall in a flush manner, because they have insufficient clearance to bend the cables (since, for example, USB and Ethernet cables require 1-2 inches of clearance before the cables can bend).

In view of the foregoing, there is a continued need for improved routers, particularly those that are more visually streamlined and attractive. More particularly, it would be desirable to most consumers to utilize a router that is configured to hide the cables and cords to which it is attached. That is, it would be desirable to most consumers to utilize a router that is configured to hide the cables and cords to which it is attached, regardless of how the router is oriented, i.e., when the router is mounted to a wall, positioned vertically, or sitting horizontally on a surface (such as a table or desk surface). As mentioned above, many of the prior art routers available today are typically configured to hide the connected cables in only one position or, at most, two positions.

### SUMMARY OF THE INVENTION

According to certain aspects of the invention, wireless Internet routers are provided. The routers generally comprise a casing that includes a front side, a backside, a top side, a bottom side, and two additional sides. The top side, bottom side, and two additional sides connect the front side to the back side, such that—when fully assembled—the casing is configured to house at least one printed circuit board of the router. The casing further includes an indentation area located in the backside thereof. In a first embodiment, the indentation area comprises two side walls, a third wall that connects the two side walls, and a surface that meets and, preferably, is integrally formed with each of the two side walls and third wall, e.g., at an approximate 90-degree angle (or other angles to create the needed indentation area). In a second embodiment, the indentation area comprises one or more straight or curved walls, and a surface that meets with the one or more straight or curved walls. The routers of the present invention further comprise a plurality of connection ports, e.g., Ethernet ports (RJ45 connectors), a power port, and a universal serial bus (USB), which may be located within a wall of the indentation area.

In addition, according to certain preferred embodiments, the routers of the present invention include one or more holes, such as two evenly spaced holes, located in the backside of the router. The one or more holes are adapted to receive a protruding element, such as a nail, screw, or other rigid/protruding element, in order to reversibly attach the router to a wall surface or router stand.

The invention provides that the indentation area and connection ports are configured such that the backside of the router is substantially adjacent to and flush with a wall surface, when (a) the router is attached to a wall surface and (b) when a plurality of cables are connected to the plurality of connection ports.

According to additional aspects of the invention, the one or more walls of the indentation area are between 4 mm and 30 mm in height (or, said another way, the indentation area will exhibit a depth between 4 mm and 30 mm relative to the backside of the router). This height (depth) will preferably correspond to the distance between the backside of the router and the surface that meets and is, preferably, integrally formed with the one or more walls of the indentation area. The invention provides that the router will preferably include a first printed circuit board attached to and stacked upon a second printed circuit board, wherein the first printed circuit board comprises the plurality of connection ports that are configured to be located adjacent to a plurality of connection port holes located in a wall of the indentation area. According to an alternative (second) embodiment, the invention provides that the motherboard includes a printed circuit board that has a plurality of connection ports that are configured to be located adjacent to a plurality of connection port holes located in a wall of the indentation area. In this embodiment, the connection ports are integrally formed into a tower that exhibits the necessary height to cause the ports to be directly adjacent with the connection port holes located in the wall of the indentation area, when the router is fully assembled. That is, the height of this tower is adapted to position the plurality of connection ports (when attached to the printed circuit board) in a manner that is immediately adjacent to the plurality of connection port holes located in the wall of the indentation area.

According to additional aspects of the invention, the wireless Internet router includes an exposed heat sink. More particularly, the invention provides that the surface that meets and is integrally formed with the one or more walls of the indentation area will include a window. A printed circuit board of the router will be equipped with a heat sink, which includes a plurality of protruding elements. The invention provides that the heat sink is configured to be disposed through the window of the casing (located in the indentation area) and, therefore, exposed to outside air when the casing is assembled and encapsulates the inner components of the router.

According to still further aspects of the invention, the wireless Internet router may include an omni antenna, which is located and enclosed within (or embedded into) the casing of the router. The invention provides that, preferably, the omni antenna will not include a rubber shield. According to yet further aspects of the present invention, a router stand is provided, which includes one or more protruding elements that are configured to be disposed into one or more holes located in the backside of the router, to reversibly attach the router to the router stand and orient the router in a slanted vertical position.

The above aspects of the present invention are described and exemplified further in the Detailed Description set forth below.

### BRIEF DESCRIPTION OF THE FIGURES

FIG. 1 is a backside, perspective view of the router described herein.

FIG. 2 is a backside, perspective view of the router described herein, which shows the router detached from the router stand that is shown in FIG. 1.

FIG. 3 is a backside view of the router described herein.

FIG. 4 is a bottom side view of the router described herein.

FIG. 5 is a disassembled view of the router described herein, which includes a single printed circuit board (PCB).

FIG. 6 is a disassembled view of the router described herein, which includes two PCBs.

FIG. 7 is an illustration of the PCB and custom sized connection ports (integrally formed into a tower), as described herein.

FIG. 8 is an illustration of the two PCB configuration described herein, with a first PCB (that comprises a plurality of connection ports) attached to and stacked upon a second PCB.

FIG. 9 is an illustration of the connection ports that are attached to the first PCB of FIG. 8.

FIG. 10 is an illustration of the custom sized connection ports that are attached to the PCB of FIG. 7.

FIG. 11 is an illustration of the router described herein connected to a series of cables and sitting on a flat surface (table).

FIG. 12 is an illustration of the router described herein connected to a series of cables and mounted to a wall surface.

FIG. 13 is an illustration of the router described herein connected to the router stand described herein.

FIG. 14 is an illustration of the router described herein, which comprises an indentation area having a single curved wall.

### DETAILED DESCRIPTION OF THE INVENTION

The following will describe, in detail, several preferred embodiments of the present invention. These embodiments are provided by way of explanation only, and thus, should not unduly restrict the scope of the invention. In fact, those of ordinary skill in the art will appreciate upon reading the present specification and viewing the present drawings that the invention teaches many variations and modifications, and that numerous variations of the invention may be employed, used and made without departing from the scope and spirit of the invention.

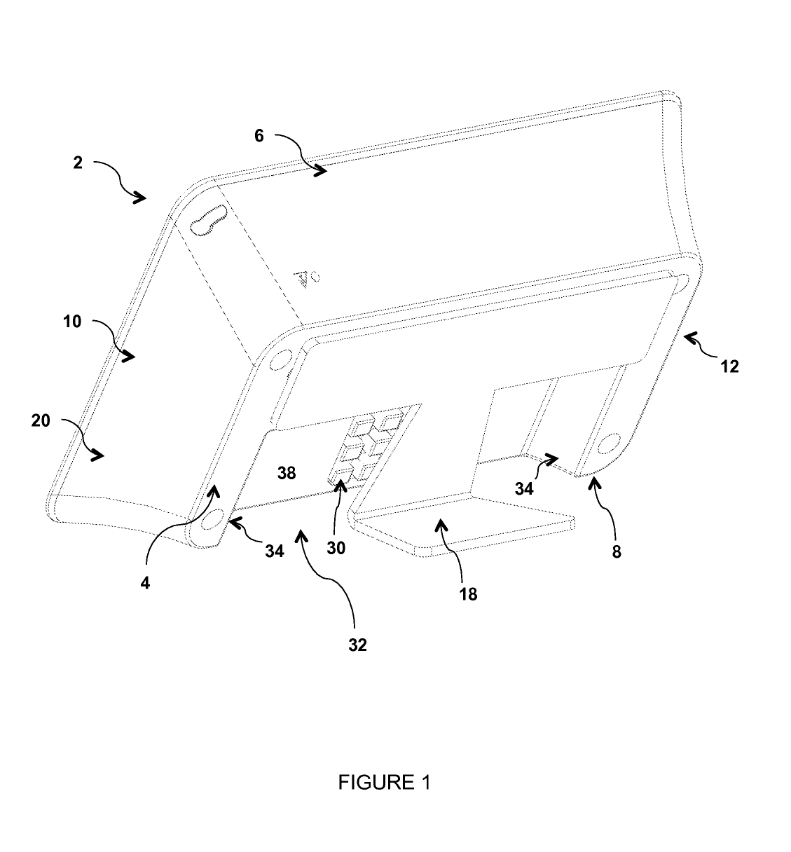

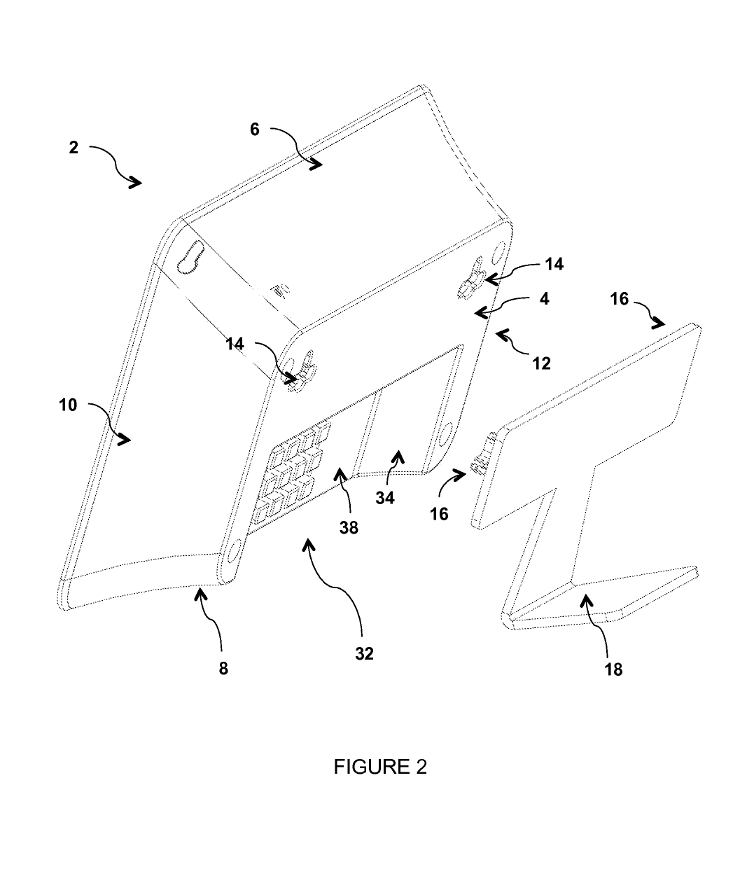

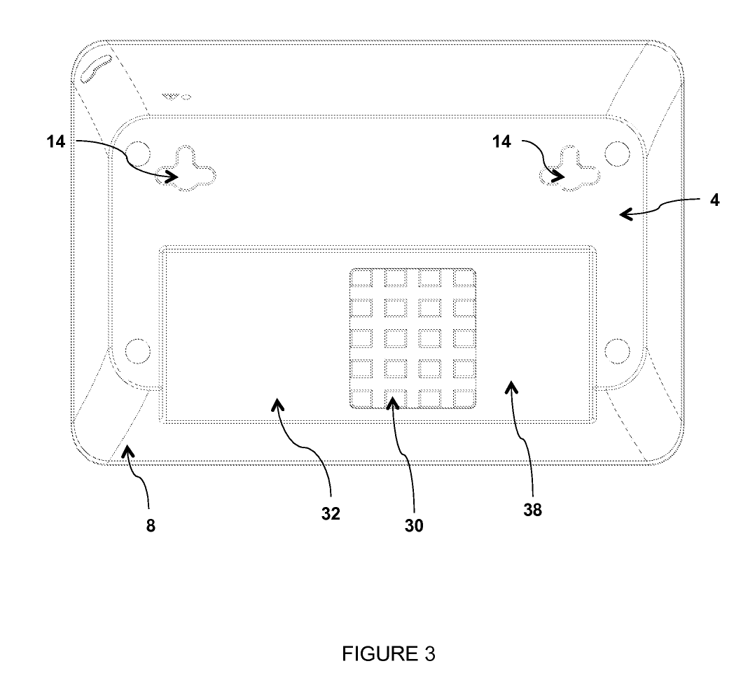

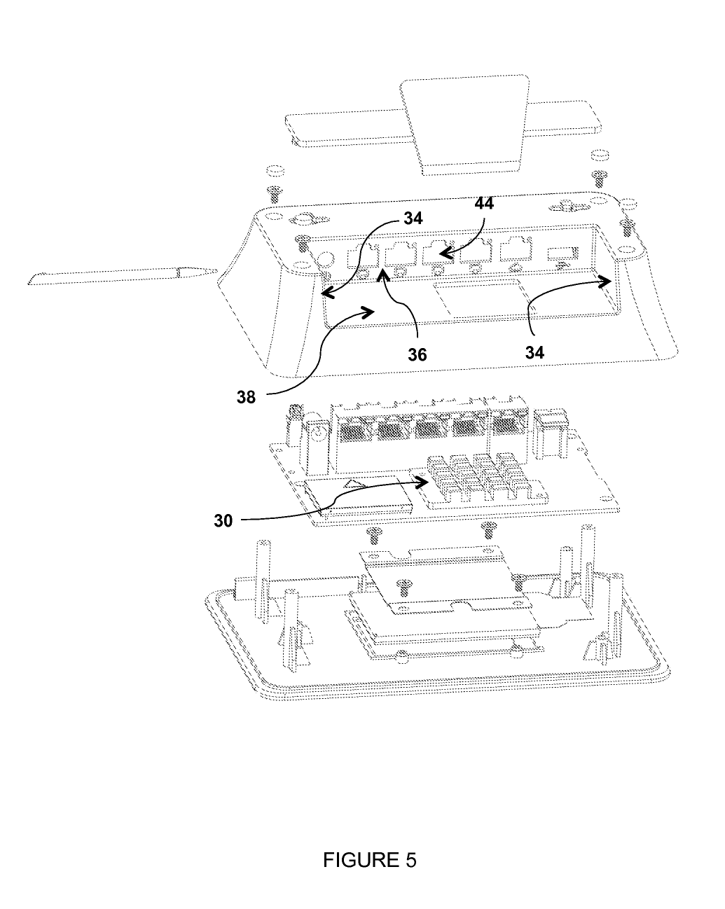

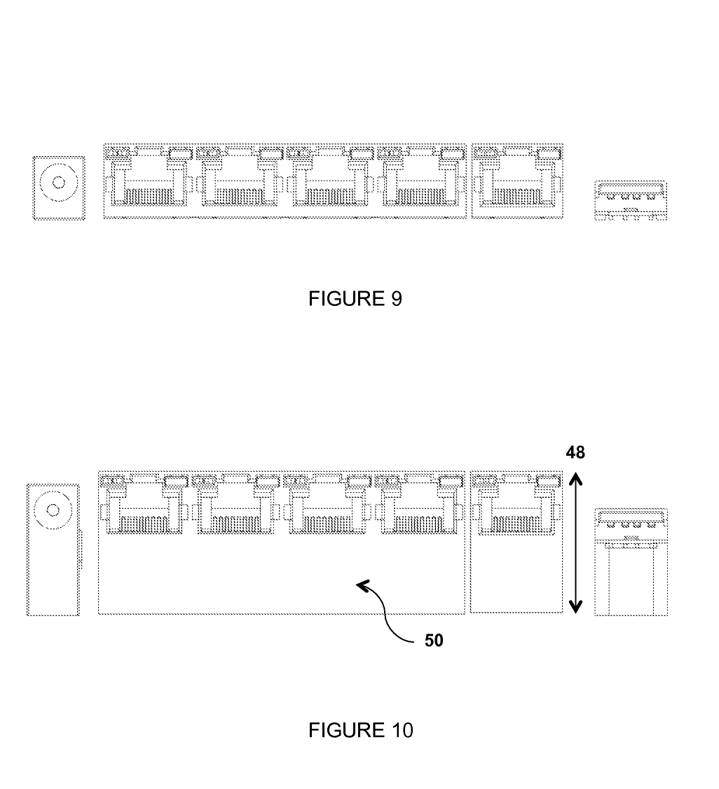

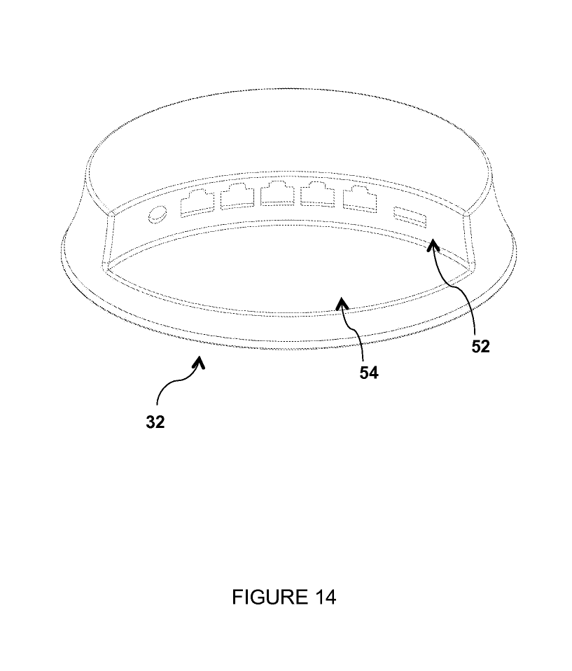

The invention generally relates to network routers, and particularly to wireless Internet routers. Referring to FIGS. 1-14, the routers of the present invention include a front side 2 (which may include a touch screen user interface) and a backside 4, as well as a top side 6, a bottom side 8, and two additional sides 10/12 that adjoin and connect the front side 2 to the backside 4. The front side 2, backside 4, top side 6, bottom side 8, and two additional sides 10/12 of the routers form a casing 20. The invention provides that the casing 20 includes an indentation area 32 located in the backside 4 of the casing 20. In a first embodiment, the indentation area 32 comprises two side walls 34, a third wall 36 that connects the two side walls 34, and a surface 38 that meets and is integrally formed with each of the two side walls 34 and third wall 36. The two side walls 34 and third wall 36 may be configured to meet at a variety of angles, including, but not limited to, an approximate 90-degree angle. In other embodiments, the indentation area 32 comprises one or more walls 52, which may be straight or curved walls, and a relatively planar surface 54 that meets with and, preferably, is integrally formed with the one or more walls 52. A non-limiting example of an indentation area 32 of this embodiment is shown in FIG. 14, which illustrates an indentation area 32 with a single curved wall 52.

According to certain preferred embodiments of the invention, the two side walls 34 and third wall 36 of the indentation area are between 4 mm and 30 mm in height or, more specifically, between about 14 mm and 20 mm in height. This height will preferably correspond to the distance between the backside 4 of the router and the surface 38 that meets and is integrally formed with each of the two side walls 34 and third wall 36 of the indentation area 32. Similarly, in the other related embodiments, such as in the router shown in FIG. 14, the indentation area 32 will exhibit a height of between 4 mm and 30 mm or, more specifically, between about 14 mm and 20 mm (i.e., the distance between the backside 4 of the router and the surface 54 that meets and is integrally formed with the one or more walls 52).

The invention further provides that the backside 4 of the router will include one or more holes 14 that are configured to receive a nail, screw, or other rigid element, which may be used to affix the router to a wall surface. In addition, the invention provides that the one or more holes 14 are further configured to receive a protruding element 16 affixed to or integrally formed with a router stand 18, such that the router may be reversibly attached to the router stand 18 and oriented in a slanted and vertical position.

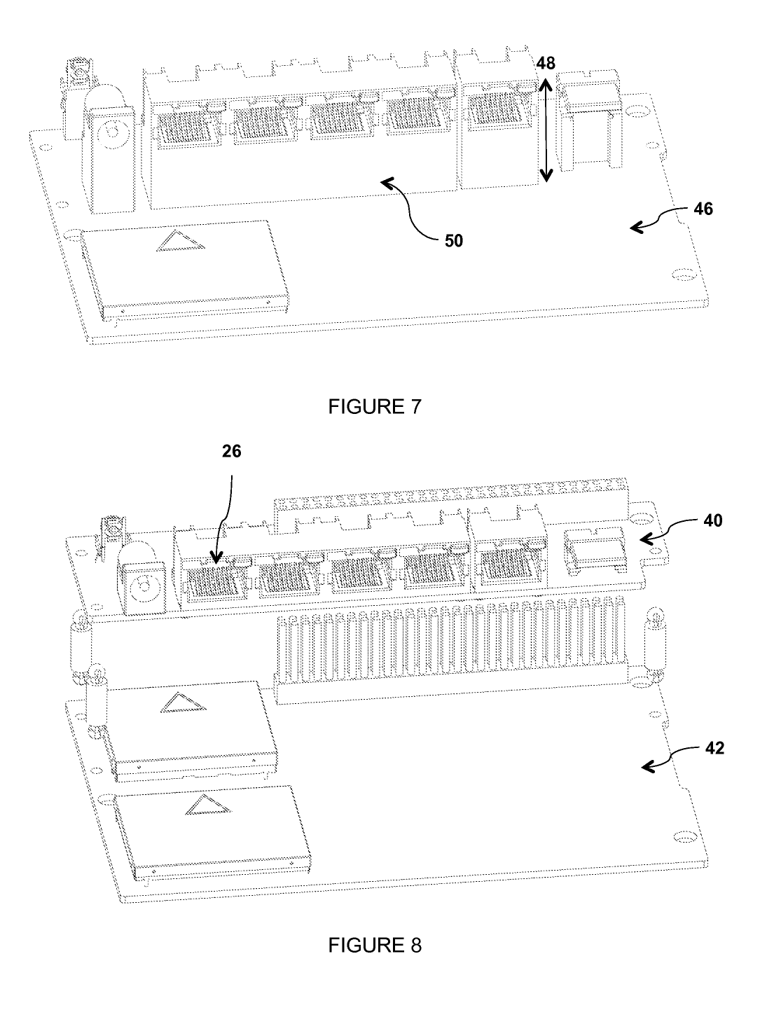

As mentioned above, the routers of the present invention include a casing 20, which encloses the various functioning components of the routers, such as the printed circuit boards (PCBs) 40,42,46 (FIGS. 7/8) of the routers. The router will be configured to comprise an internal clock, a central processing unit (CPU), dynamic random access (DRAM) memory, read only memory (ROM) or flash memory, and other functioning components. These various internal and functioning parts of the routers are generally known. For example, the CPU will function to read incoming message headers and determine the proper destination of each message. The DRAM will be configured to store the operating system software for the router, and run configuration files and routing tables. The router may further comprise non-volatile random access memory, which is configured to retain data when the power is off (and may serve as a backstop by storing the router's configuration file). The flash memory of the router may also hold such data.

According to certain preferred embodiments, the invention provides that the routers comprise a series of connection ports 26, e.g., Ethernet ports (RJ45 connectors), a power port, universal serial bus (USB), and others, which are recessed within the casing 20 of the router, particularly the indentation area 32 of the backside 4 of the router. More particularly, the connection ports 26 may be located within the third wall 36 (or other wall 52) of the indentation area 32 (or, alternatively, within either (or both) of the two side walls 34). The plurality of connection ports 26 may be oriented to face towards the bottom side 8 of the router (e.g., when located within the third wall 36 of the indentation area 32). Alternatively, the plurality of connection ports 26 may be oriented sideways (e.g., when located within the two side walls 34) or in a slanted manner, so long as the connection ports 26 are recessed within the indentation area 32.

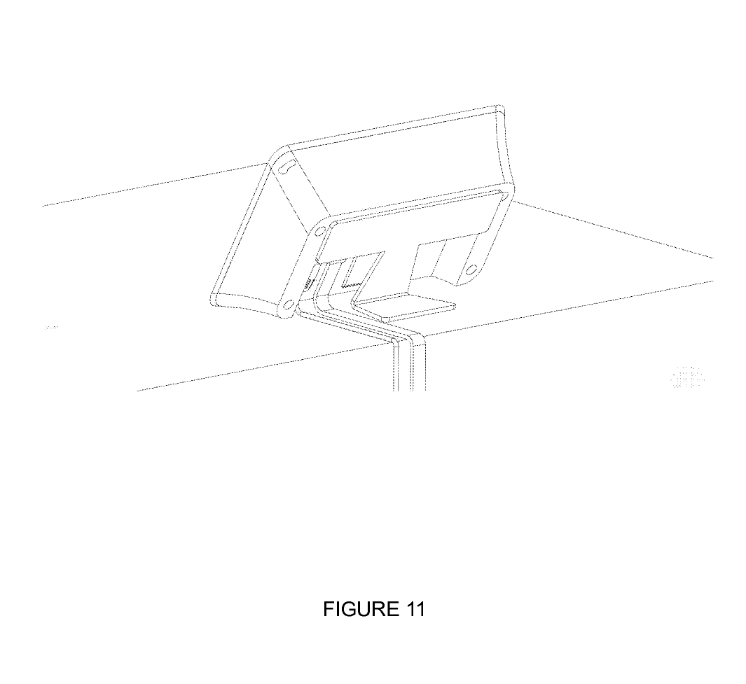

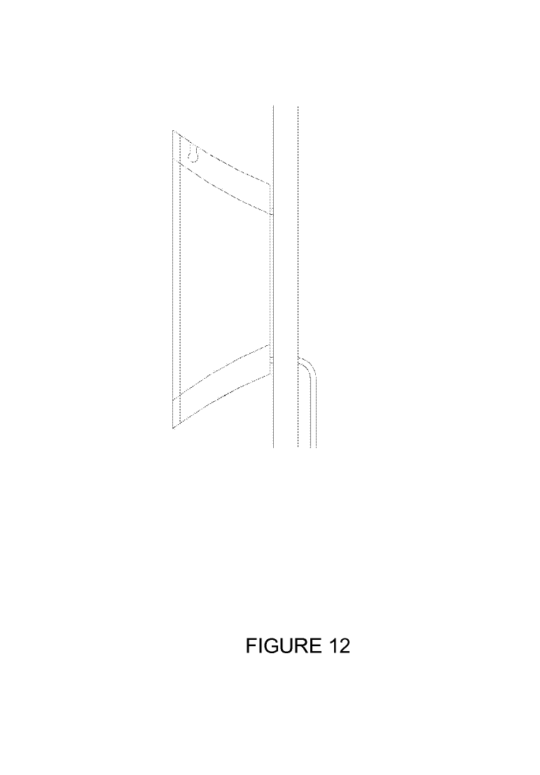

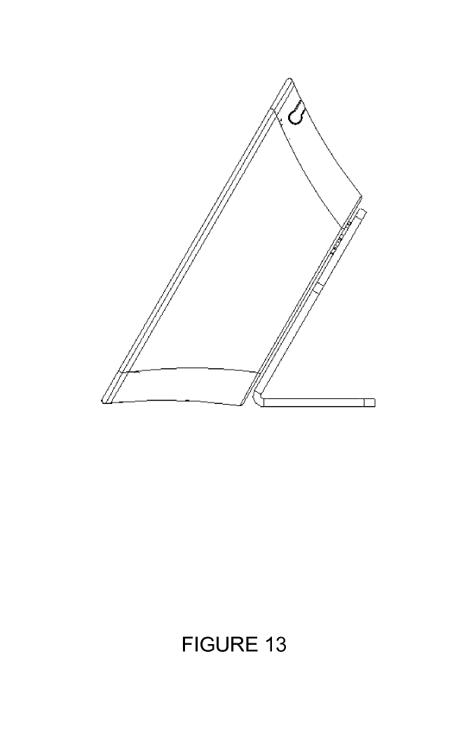

The invention provides that the cables that are reversibly connected to such ports 26 are hidden from view. More particularly, the invention provides that such cables are hidden from view, when the router is positioned vertically and mounted to a wall through the one or more holes 14 (FIG. 12), or positioned in a vertically slanted position (e.g., when attached to the router stand 18, as shown in FIGS. 11 and 13), or positioned horizontally (e.g., when positioned on a flat surface). The invention provides that the configuration of the indentation area 32, and recessed position of the connection ports 26, enable the router to exhibit such features and effectively hide cables when oriented in such different positions.

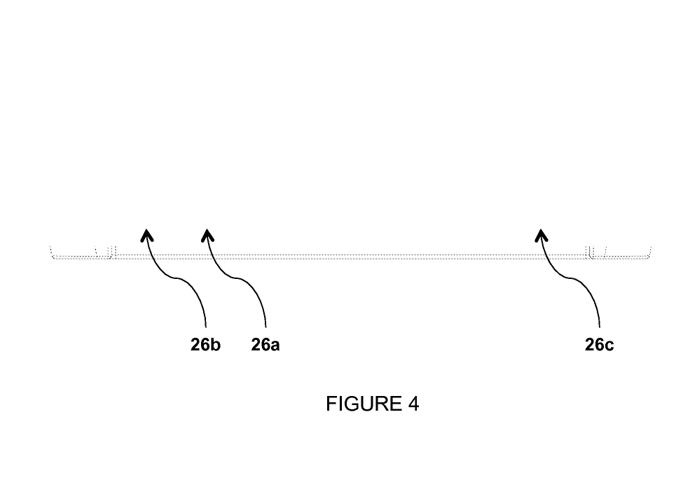

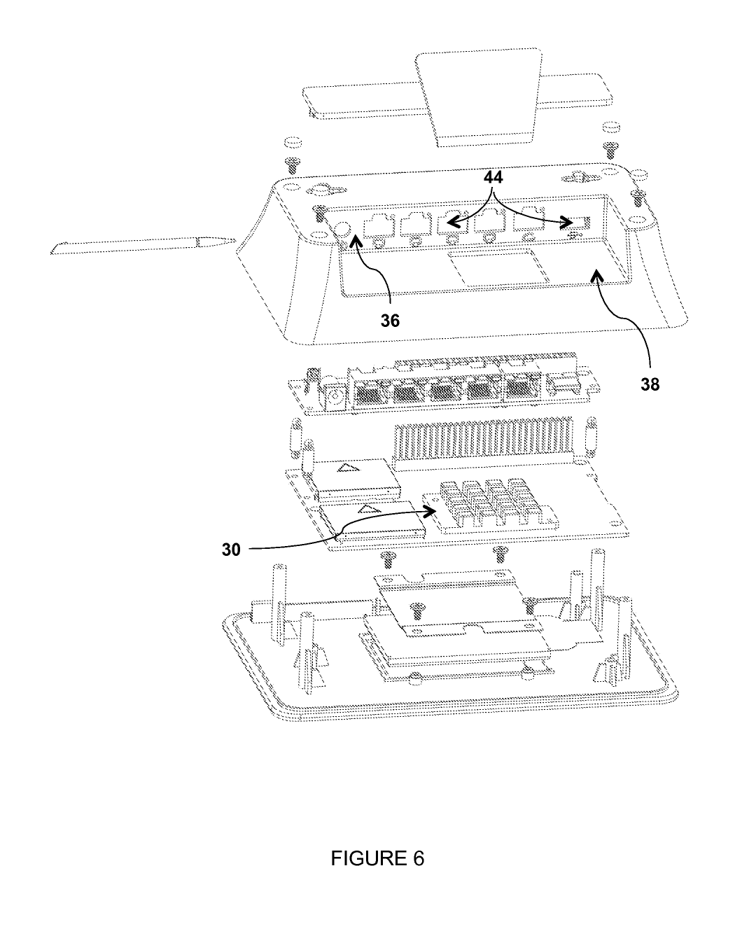

The invention provides that the connection ports 26, e.g., Ethernet ports (RJ45 connectors) 26a, power port 26b, USB port 26c (FIG. 4), and others, are recessed and positioned within the backside 4 of the router, in accordance with a couple different embodiments. In a first embodiment of the present invention, the router comprises two printed circuit boards 40/42 (PCBs) that are interconnected and comprise standard-sized connection ports 26 (FIG. 8). More particularly, in this embodiment, the invention provides that the router will preferably include a first printed circuit board 40 attached to and stacked upon a second printed circuit board 42. The first printed circuit board 40 will include the plurality of connection ports 26 that are configured to be located adjacent to a plurality of connection port holes 44 (FIG. 6) located in the third wall 36 (or side walls 34 or other wall 52) of the indentation area 32.

In a second embodiment of the present invention, the router comprises a single PCB 46 and connection ports 26 that are taller than a standard connection port 26 (FIG. 7). More particularly, in this second embodiment, the connection ports 26 are sufficient in height 48 to position the plurality of connection ports 26 (when attached to the printed circuit board 46) in a manner that is immediately adjacent to the plurality of connection port holes 44 (FIG. 6) located in the third wall 36 (or side walls 34 or other wall 52) of the indentation area 32. In certain embodiments, the Ethernet ports (RJ45 connectors) 26a (and, optionally, the power port 26b) may exhibit a greater height 48 than the USB port 26c (FIG. 4). In this second embodiment, the connection ports 26 are integrally formed into a tower 50 that provides the needed height 48 (without stacking one PCB on another). The invention provides that it is the height of these towers that is preferably adapted to position the plurality of connection ports 26 (when attached to the printed circuit board 46) in a manner that is immediately adjacent to a plurality of connection port holes 44 located in the third wall 36 (or other wall 52) of the indentation area 32.

Many of the prior art routers are configured to be mounted to a wall surface, but do not have an adequate indentation area to provide sufficient clearance for cables to bend. The invention provides that the connection ports 26 are recessed within the casing 20 of the router (the backside 4 of the router), in order to create sufficient room for the associated cables to bend and be hidden from view (between the router and wall surface).

According to further preferred embodiments, the invention provides that the routers will comprise an omnidirectional (omni) antenna, which is an antenna that is configured to radiate signal wave power uniformly in all directions in one plane. The invention provides that, preferably, the omni antenna will not comprise a rubber shield surrounding the antenna. Furthermore, the invention provides that the antenna is preferably embedded into the casing 20 (or positioned within the casing 20) of the router, such that it will not be visible from outside the router. The invention provides that, preferably, the antennas will not be PCB antennas, nor metal antennas, but rather an omni-type antenna (without the rubber shield) embedded in the casing 20. The invention provides that employing and installing an omni antenna in the router provides a desirably strong network signal, while enhancing the appearance of the router by embedding the antenna into the casing 20 (or within the casing 20) of the router.

According to still further embodiments, the routers of the invention will preferably comprise an exposed heat sink 30, preferably within the backside 4 of the router, which comprises a plurality of protruding elements that are configured to maximize the surface area (over the defined area of the heat sink 30) to encourage the release and dissipation of heat that is generated by the router. The invention provides that the router may, at times, generate excessive heat that must be quickly mitigated. The invention provides that the exposed heat sink 30 allows the router to exhibit a desirably streamlined and smaller dimension, while still dissipating the necessary amount of heat without the use of noisy fans (which are also susceptible to mechanical failures).

The invention provides that the router will contain a user interface on the front side 2 of the router. The user interface will include a series of controls to operate the router and to adjust the settings thereof. The invention provides that the user interface may comprise an LCD/touch screen interface (or, alternatively, a more traditional push button interface). When the router employs the use of an LCD interface, the router may, optionally, be further equipped with a sensor that measures the current orientation of the router and user interface. This way, the LCD interface may rotate and present information to a user in a consistent and readable manner, regardless of how the router is turned and oriented in three-dimensional space, e.g., vertical on a wall (with the cables traveling downwards) or horizontal on a table (with the cables traveling backward).

According to yet further embodiments of the present invention, a router stand 18 is provided, which includes one or more protruding elements 16 that are configured to be disposed into one or more holes 14 located in the backside 4 of the router, to reversibly attach the router to the router stand 18 and orient the router in a slanted vertical position.

The many aspects and benefits of the invention are apparent from the detailed description, and thus, it is intended for the following claims to cover all such aspects and benefits of the invention that fall within the scope and spirit of the invention. In addition, because numerous modifications and variations will be obvious and readily occur to those skilled in the art, the claims should not be construed to limit the invention to the exact construction and operation illustrated and described herein. Accordingly, all suitable modifications and equivalents should be understood to fall within the scope of the invention as claimed herein.

What is claimed is:

1. A wireless Internet router, which comprises:
(a) a casing that comprises a front side, a backside, a top side, a bottom side, and two additional sides, wherein the top side, bottom side, and two additional sides connect the front side to the back side, wherein the casing is configured to house one or more printed circuit boards of the router;
(b) an indentation area located in the backside of the casing, wherein the indentation area comprises one or more walls, and a surface that meets the one or more walls;
(c) a plurality of connection ports located within the one or more walls of the indentation area; and
(d) one or more holes located in the backside of the router, which are adapted to receive a protruding element to reversibly attach the router to a wall surface or router stand.

2. The wireless Internet router of claim 1, wherein the indentation area exhibits a height of about 4 mm to 30 mm.

3. The wireless Internet router of claim 2, wherein the indentation area and connection ports are configured such that the backside of the router is substantially adjacent to and flush with a wall surface when (a) the router is attached to the wall surface and (b) when a plurality of cables are connected to the plurality of connection ports.

4. The wireless Internet router of claim 3, wherein the router comprises a first printed circuit board attached to and stacked upon a second printed circuit board, wherein the first printed circuit board comprises the plurality of connection ports which are configured to be located adjacent to a plurality of connection port holes located in the one or more walls of the indentation area.

5. The wireless Internet router of claim 3, wherein the router comprises a printed circuit board that comprises the plurality of connection ports, which are integrally formed into a tower that positions the connection ports adjacent to a plurality of connection port holes located in the one or more walls of the indentation area.

6. The wireless Internet router of claim 3, wherein:
(a) the surface that meets the one or more walls of the indentation area comprises a window;
(b) the router comprises a printed circuit board that comprises a heat sink, which comprises a plurality of protruding elements; and
(c) the heat sink is configured to be disposed through said window and exposed when the casing is assembled and encapsulates the printed circuit board.

7. The wireless Internet router of claim 3, which further comprises an omni antenna, which is located and enclosed within or embedded into the casing.

8. The wireless Internet router of claim 7, wherein the omni antenna does not comprise a rubber shield.

9. The wireless Internet router of claim 3, wherein the connection ports comprise Ethernet ports (RJ45 connectors), a power port, and a universal serial bus (USB).

10. The wireless Internet router of claim 3, which further comprises the router stand, which comprises one or more protruding elements that are configured to be disposed into one or more holes located in the backside of the router, to reversibly attach the router to the router stand and orient the router in a slanted vertical position.

11. A wireless Internet router assembly, which comprises:
(a) a casing that comprises a front side, a backside, a top side, a bottom side, and two additional sides, wherein the top side, bottom side, and two additional sides connect the front side to the back side, wherein the casing is configured to house one or more printed circuit boards of the router;
(b) an indentation area located in the backside of the casing, wherein the indentation area comprises one or more walls, and a surface that meets the one or more walls, wherein the indentation area exhibits a height of about 4 mm to 30 mm;
(c) a plurality of connection ports located within the one or more walls of the indentation area;
(d) one or more holes located in the backside of the router, which are adapted to receive a protruding element to reversibly attach the router to a wall surface or router stand; and
(e) a router stand, which comprises one or more protruding elements that are configured to be disposed into the one or more holes located in the backside of the router, to reversibly attach the router to the router stand and orient the router in a slanted vertical position.
